(19) United States
(12) Patent Application Publication
(10) Pub. No.: US 2006/0145329 A1
(43) Pub. Date: Jul. 6, 2006

(54) Lead frame for semiconductor device

(75) Inventor: Isao Ozawa, Chigasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/297,457

(22) Filed: Dec. 9, 2005

(30) Foreign Application Priority Data
Dec. 27, 2004 (JP) 2004-377370
Mar. 17, 2005 (JP) 2005-077451

(51) Int. Cl. H01L 23/52; H01L 23/48

(52) U.S. Cl. 257/692; 257/694; 257/695

(57) ABSTRACT

A lead frame for semiconductor device has at least one bed frame capable of supporting a dual-pin-type chip, a plurality of suspension pin frames which extend from the bed frame in a first direction, and are disposed apart from each other in a second direction, and at least two beam frames which extend from the plurality of suspension pin frames in the second direction, and connect the plurality of suspension pin frames at both sides of the chip by sandwiching the chip.

### CROSS REFERENCE TO RELATED APPLICATIONS

This application is based upon and claims the benefit of priority from the prior Japanese Patent Applications No. 2004-377370 filed on Dec. 27, 2004 and No. 2005-77451 filed on Mar. 17, 2005, the entire contents of which are incorporated herein by reference.

### BACKGROUND OF THE INVENTION

1. Field of the Invention

The present invention relates to a lead frame for a semiconductor device capable of mounting a chip.

2. Related Art

Portable memory cards, which are composed of a flash memory or the like contained in a thin plastic package, have become popular. Such a thin plastic package has outer leads disposed outside of the package and inner leads connected to the outer leads. A pad of a chip is connected to the inner leads by bonding wires. The chip and the inner leads are sealed with an epoxy resin (see Japanese Patent No. 1994757).

Recently, various electronic apparatus including PCs and cellular phones have a memory card slot. The memory card has to be inserted to or removed from the memory card slot in a predetermined direction. However, during insertion or removal of a memory card, a user may accidentally twist the memory card in a direction other than the predetermined direction.

Most memory cards have a thin plastic package, which has low torsional strength. Thus, if a torsional force greater than a certain level is applied to such a memory card, the package may be cracked, and the chip in the memory card may be damaged.

### SUMMARY OF THE INVENTION

According to one embodiment of the present invention, a lead frame for semiconductor device, comprising:

at least one bed frame capable of supporting a dual-pin-type chip;

a plurality of suspension pin frames which extend from the bed frame in a first direction, and are disposed apart from each other in a second direction; and

at least two beam frames which extend from the plurality of suspension pin frames in the second direction, and connect the plurality of suspension pin frames at both sides of the chip by sandwiching the chip.

Furthermore, according to one embodiment of the present invention, a lead frame for semiconductor device, comprising:

first and second bed frames which are disposed apart from each other in a first direction and mount a dual-pin-type chip;

first and second suspension pin frames which are disposed in a second direction by sandwiching the first bed frame to support the first bed frame;

third and fourth suspension pin frames which are disposed in a second direction by sandwiching the second bed frame to support the second bed frame;

a first beam frame which connects the first and third suspension pin frames; and

a second beam frame which connects the second and fourth suspension pin frames.

Furthermore, according to one embodiment of the present invention, a lead frame for semiconductor device, comprising:

a flat bed frame capable of supporting a whole bottom surface of a chip, which has a plurality of concaves at a bottom surface side thereof; and

first and second suspension pin frames which are formed integrated with the flat bed frame, and extend outside along two opposite edges of the flat bed frame, portions of the first and second suspension pin frames being cut to form cut portions.

### BRIEF DESCRIPTION OF THE DRAWINGS

FIG. 1 is a perspective view of a package for a semiconductor device according to a First Embodiment of the present invention, which shows a configuration of a lead frame.

FIG. 2 is a cross-sectional view taken along the line A-A in FIG. 1.

FIG. 3 is a cross-sectional view taken along the line B-B in FIG. 1.

FIG. 4 is a cross sectional view of a memory IC 20 according to this embodiment.

FIG. 5 is a diagram showing a direction twisting a memory IC 20 when measuring torsional force.

FIG. 6 is a diagram showing an example in which a plurality of rows of punch holes 23 are formed in the first to fourth suspension pin frames 4 to 7.

FIG. 7 is a three-view drawing showing the outline of a memory card 30 embedding the memory IC 20.

FIG. 8 is a diagram showing a mounted structure of the memory card 30.

FIG. 9 is a cross-sectional view taken along the line A-A in FIG. 8.

FIG. 10 is a perspective view of a memory IC 20 according a Second Embodiment.

FIG. 11 is a cross-sectional view taken along the line A-A in FIG. 10.

FIG. 12 is a perspective view of a package of a memory IC 20.

FIG. 13 is a cross-sectional view taken along the line A-A in FIG. 12.

FIG. 14 is a schematic diagram for illustrating a multi-row frame 40.

FIG. 15 is a diagram showing an example in which the concaves 46 have a circular shape.

FIG. 16 is a diagram showing an example in which the concaves 46 have an elliptical shape.

FIG. 17 is a diagram showing examples in which the concaves 46 have rectangular shapes.

FIG. 18 is a diagram showing examples in which the concaves 46 have rectangular shapes.

FIG. 19 is a cross-sectional view taken along the line B-B in FIG. 12.

### DETAILED DESCRIPTION OF THE INVENTION

Hereinafter, embodiments of the present invention will be described with reference to the drawings.

### FIRST EMBODIMENT

FIG. 1 is a perspective view of a package for a semiconductor device according to a First Embodiment of the present invention, which shows a configuration of a lead frame. The semiconductor device shown in FIG. 1 is a dual-pin-type chip 1 sealed with an epoxy resin by resin-molding. Any kinds of chip 1 are available in this embodiment. For example, the semiconductor device of FIG. 1 may be a flash memory chip 1. Hereinafter, the semiconductor device according to the present invention will be described with one example of a memory IC embedding the flash memory as the chip 1. In FIG. 1, a location of the chip 1 mounted is shown by a dotted line.

The memory IC shown in FIG. 1 has a first bed frame 2 and a second bed frame 3 which support the chip 1 and are arranged apart from each other in the X direction, a first suspension pin frame 4 and a second suspension pin frame 5 which support the first bed frame 2 and are arranged along the Y direction by sandwiching the first bed frame 2, a third suspension pin frame 6 and a fourth suspension pin frame 7 which support the second bed frame 3 and are arranged along the Y direction by sandwiching the second bed frame 3, a first beam frame 8 for interconnecting the first suspension pin frame 4 and the third suspension pin frame 6, a second beam frame 9 for interconnecting the second suspension pin frame 5 and the fourth suspension pin frame 7, inner leads 10 disposed at the outer sides of the first bed frame 2 and the second bed frame 3, and outer leads 11 which is connected to the inner leads and arranged to the outside of the package.

The first and second bed frames 2 and 3 are made of an alloy material, for example. The chip 1 is connected to the first and second bed frame 2 and 3 by a mount material made of an epoxy resin, for example. In order to enhance conductivity, the inner leads 10 are plated with silver at locations to be connected to bonding wires. The chip 1 is fixed to the frame 2 by an adhesive la. The bonding wires are made of a gold alloy, for example. The outer leads 11 are made of an alloy material, for example, and the surface thereof is plated with tin/lead, tin/copper, or tin/silver.

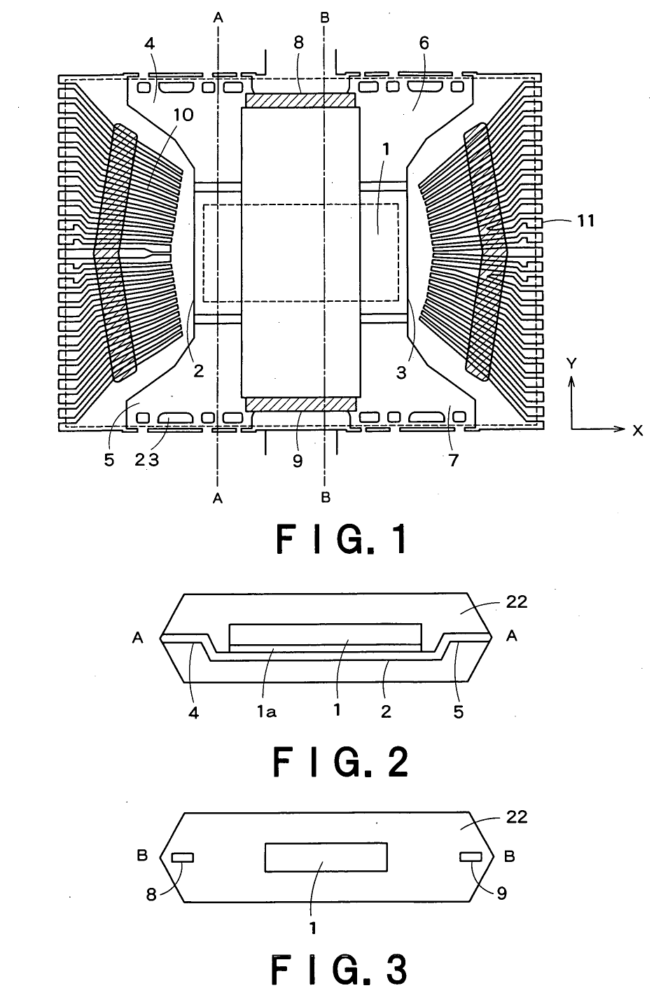

FIG. 2 is a cross-sectional view taken along the line A-A in FIG. 1, and FIG. 3 is a cross-sectional view taken along the line B-B in FIG. 1. As shown in FIG. 2, the first bed frame 2, the first suspension pin frame 4 and the second suspension pin frame 5 are formed of one conductive plate. Steps are formed so that the first bed frame 2 becomes lower than the first and second suspension pin frames 4 and 5.

Similarly, the second bed frame 3, the third suspension pin frame 6 and the fourth suspension pin frame 7 are formed of one conductive plate. Steps are formed so that the second bed frame 3 becomes lower than the third and fourth suspension pin frames 6 and 7.

As shown in FIG. 2, the chip 1 is sealed with a molded resin 22. The steps between the first bed frame 2 and the first and second suspension pin frames 4 and 5, and the steps between the second bed frame 3 and the third and fourth suspension pin frames 6 and 7 are set so that a distance between an upper surface of the chip 1 and an upper surface of the epoxy resin 22 becomes equal to a distance between a bottom surface of the chip 1 and a bottom surface of the epoxy resin 22.

According to this embodiment, the separated first and second bed frames 2 and 3 support the chip 1, and the bed frame is not arranged in the vicinity of a center portion of the chip 1, as can be seen from FIG. 3.

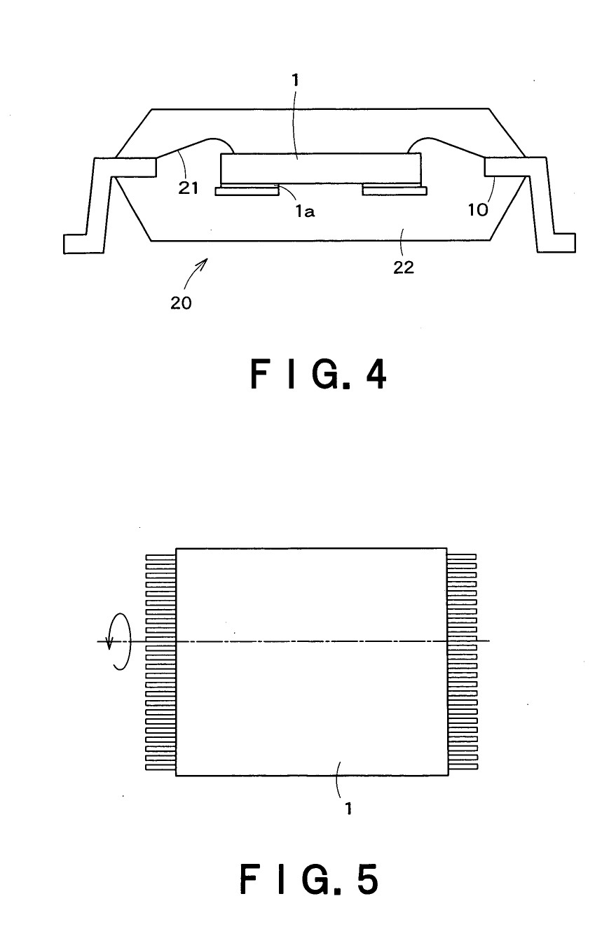

FIG. 4 is a cross sectional view of a memory IC 20 according to this embodiment. As shown in this drawing, the chip 1 is connected to the inner leads 10 by bonding wires 21, and then molded with the epoxy resin 22.

When sealing with the epoxy resin 22, if the molding speed differs between the resin 22 above the inner leads 10 and the resin 22 below the inner leads 10, the inner leads 10 and the bed frames 2 and 3 are loaded, leading to displacement of the bed frames 2 and 3 or deformation of the inner leads 10. In addition, since the resin 22 above the inner leads 10 and the resin 22 below the inner leads 10 are physically separated from each other, adhesion between the resins 22 is reduced, and the resins 22 easily peel off.

Thus, according to this embodiment, the first to fourth suspension pin frames 4 to 7 have a plurality of punch holes 23 as shown in FIG. 1. When the resin 22 to be molded is injected, the resin 22 spreads uniformly above and below the inner leads 10 through the punch holes 23. Therefore, a substantially equal molding speed can be achieved above and below the inner leads 10. In addition, since the resin 22 above the inner leads 10 and the resin 22 below the inner leads 10 are in direct contact with each other through the punch holes 23, the strength of the sealing is improved, and defects such as peel-off, hardly occur.

In addition, according to this embodiment, the steps between the bed frames 2 and 3 and the suspension pin frame 22 are set so that the distance between the upper surface of the chip 1 and the upper surface of the epoxy resin 22 becomes equal to the distance between the bottom surface of the chip 1 and the bottom surface of the epoxy resin 22. Therefore, the molding speeds of the resins 22 above and below the chip 1 become equal, thereby preventing displacement or the like of the bed frames 2 and 3.

The inventor performed a measurement of torsional strength in the cases where the first and second beam frames 8 and 9 are provided as shown in FIG. 1 and where the first and second beam frames 8 and 9 are not provided. In this measurement, a torsional force is applied around an axis rotated about 90 degrees from the direction of arrangement of pins of the memory IC 20, as shown in FIG. 5. The measurement result showed that the torsional strength in the case where the beam frames were provided was 2.71 kgf, and the torsional strength in the case where no beam frame was provided was 2.28 kgf, and thus, the beam frames provide a nearly-20% improvement of torsional strength.

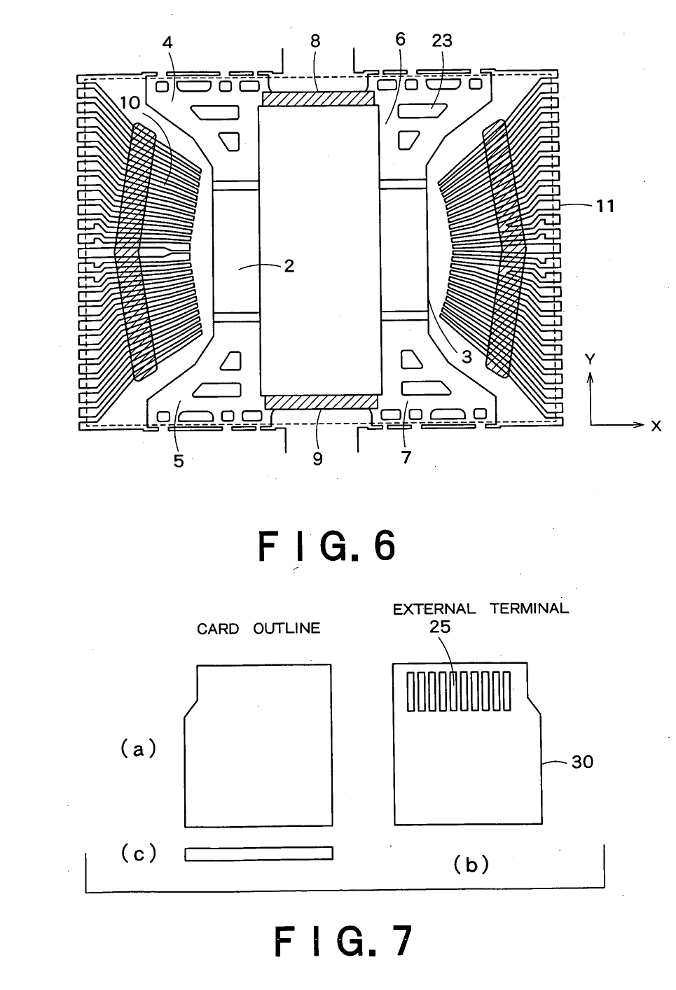

FIG. 6 shows an example in which a plurality of rows of punch holes 23 are formed in the first to fourth suspension pin frames 4 to 7. Forming such a plurality of rows of punch holes 23 as shown in this drawing further improves adhesion between the resin 22 above the inner leads 10 and the resin 22 below the inner leads 10. The number and size of the punch holes 23 are not specifically limited and can be determined based on the material, size or the like of the suspension pin frames.

The memory IC 20 according to this embodiment can be mounted on a printed circuit board, various types of memory cards, or the like. FIG. 7 is a three-view drawing showing the outline of a memory card 30 embedding the memory IC 20 according to this embodiment, in which FIG. 7A is a top view, FIG. 7B is a bottom view, and FIG. 7C is a side view. The bottom surface of the memory card 30 is provided with an external terminal 25.

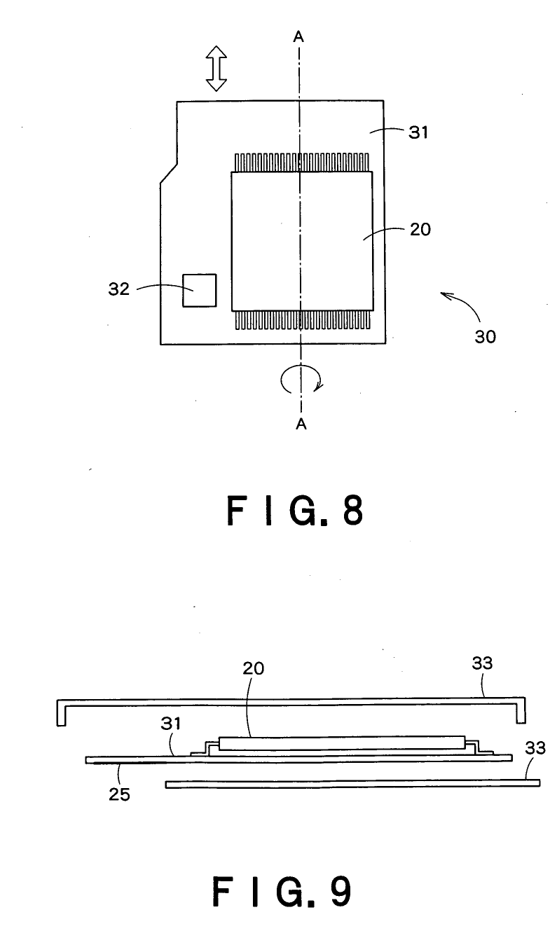

FIG. 8 shows a mounted structure of the memory card 30, and FIG. 9 is a cross-sectional view taken along the line A-A in FIG. 8. As shown in FIG. 8, the memory IC 20 according to this embodiment, which embeds a NAND-type flash memory, and a memory controller 32 for controlling read/write from/to the IC 20 are provided on a mounting substrate 31. The mounting surface 31 is covered with a card case 33.

The memory card 30 shown in FIG. 8 is inserted to or removed from a card slot (not shown) in the direction indicated by the arrow in FIG. 8. During insertion or removal, the user may accidentally twist the memory card 30 around the axis along the direction of insertion or removal. However, since the memory IC 20 according to this embodiment has the beam frames 8 and 9 as described above, the memory IC 20 has a high torsional strength and can be prevented from being damaged even if the user twists the memory card 30 to some degree.

As described above, according to the First Embodiment, since the first and second bed frames 2 and 3 separated from each other are interconnected by the beam frames 8 and 9 at the both sides of the chip 1, the memory IC 20 has an improved torsional strength and is less susceptible to damage.

### SECOND EMBODIMENT

In the First Embodiment described above, the first and second bed frames 2 and 3 separated from each other support the chip 1. However, it is not inevitable to separate the bed frames.

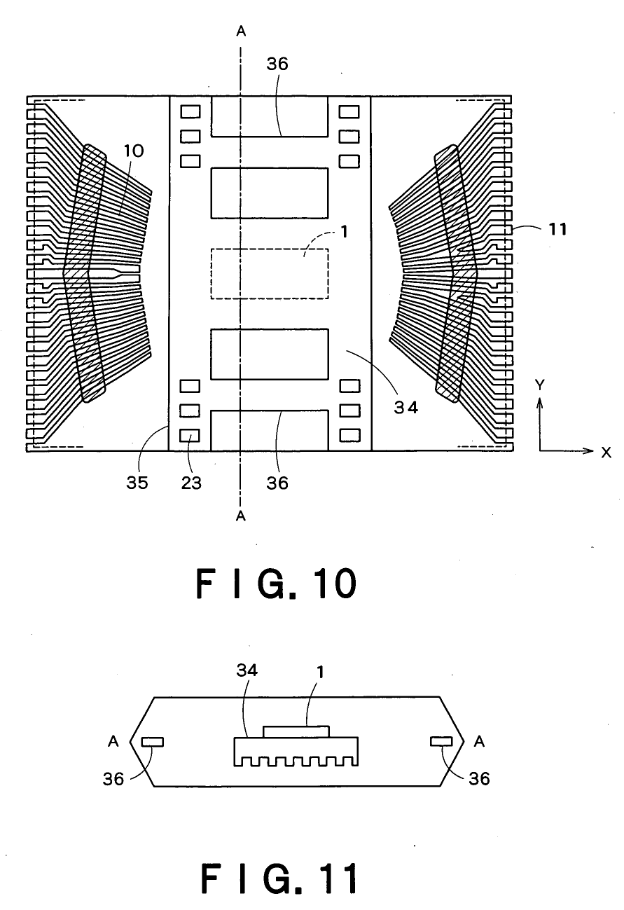

FIG. 10 is a perspective view of a memory IC 20 according a Second Embodiment of the present invention. As shown in FIG. 10, the memory IC 20 has a single-piece bed frame 34 for supporting the whole bottom surface of a chip 1, four suspension pin frames 35 extending from the corners of the bed frame 34 in the Y direction, and two beam frames 36 extending in the X direction and each interconnecting two suspension pin frames 35 arranged oppositely.

The suspension pin frames 35 have punch holes 23 similar to those shown in FIG. 1. Inner leads 10 are disposed at the outer sides of the bed frame 34 and the suspension pin frames 35, and a pad of the chip 1 is connected to the inner leads 10 by bonding wires 21.

The chip 1 is in contact with the bed frame 34 over the whole surface thereof. The chip 1 is connected to the bed frame 34 by a mount material made of an epoxy resin 22, for example.

FIG. 11 is a cross-sectional view taken along the line A-A in FIG. 10. As shown in FIG. 11, the bottom surface of the bed frame 34 is provided with concavity and convexity. By providing such concavity and convexity, a contact force between the resin 22 used for mold and the bed frame 34 is strengthened, thereby preventing defects such as peel-off of the resin 22.

As described above, according to the Second Embodiment, since the whole bottom surface of the chip 1 is in contact with the bed frame 34, the chip 1 can be more stably connected to the bed frame 34. In addition, as in the First Embodiment, the suspension pin frames 35 can increase the torsional strength of the memory IC 20.

### THIRD EMBODIMENT

A Third Embodiment is a modification of the Second Embodiment. When the chip is not so large, the separated bed frames similar to those of the First Embodiment can be used to support the chip without any problems. However, if the chip is large, the strength of the separate bed frames may be insufficient, and defects such as bending of the frames, may occur.

Thus, when the chip size is large, a flat bed frame that supports the whole bottom surface of the chip is preferably used. The flat bed frame has a higher torsional strength than the separate bed frames, and thus, a sufficient torsional strength can be achieved without the beam frames described above.

However, when a molding resin is injected, there is high possibility that the flat bed frame produces different injection speeds above and below the frame. Therefore, defects may occur, such as a tilt of the frame and a disconnection of a bonding wire due to application of an unallowable force.

In addition, adhesion between the flat bed frame and the molding resin is not so good. Therefore, when reflow processing or the like is performed to mount the completed chip onto a substrate, the flat bed frame and the molding resin may peel off each other in the package.

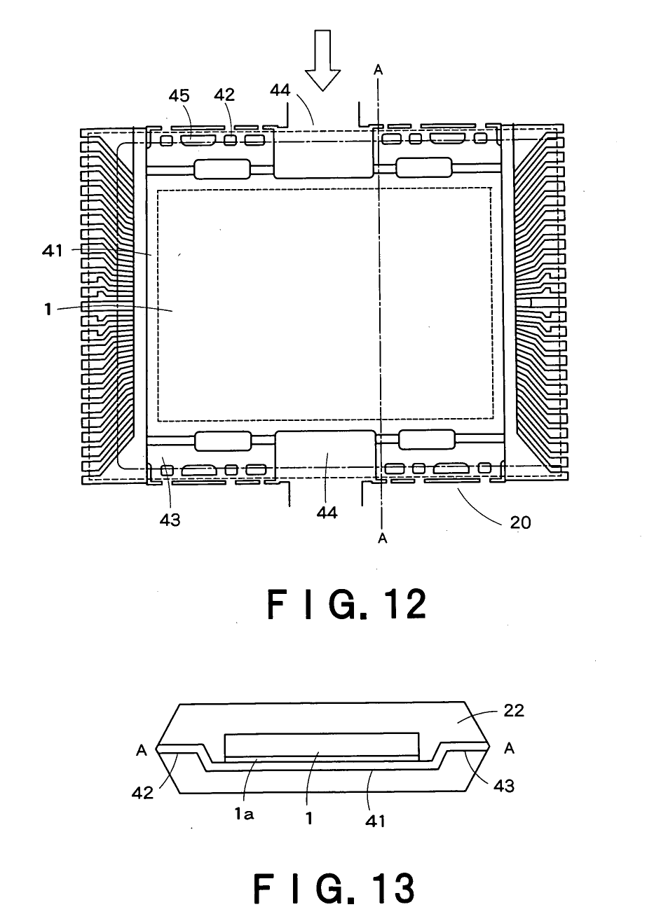

The Third Embodiment described below is characterized in that a flat bed frame can be used without having any of the defects described above. FIG. 12 is a perspective view of a package of a memory IC 20 according to the Third Embodiment of the present invention. In FIG. 12, the location of a chip 1 mounted is indicated by a dotted line. FIG. 13 is a cross-sectional view taken along the line A-A in FIG. 12.

As shown in FIG. 12, this embodiment is intended for mounting of a large chip 1. A memory IC shown in FIG. 12 has a flat bed frame 41 capable of supporting the whole bottom surface of the chip 1, and a first suspension pin frame 42 and a second suspension pin frame 43 disposed at the outer sides of opposing two edges of the flat bed frame 41.

The first and second suspension pin frames 42 and 43 are made of the same material as the flat bed frame 41 and formed integrally therewith. As shown in FIG. 13, there are steps between the first and second suspension pin frame 42 and 43 and the flat bed frame 41, and the first and second suspension pin frame 42 and 43 are formed at a location higher than the flat bed frame 41.

Each of the first and second suspension pin frames 42 and 43 has a notch 44. The notches 44 are formed at a location opposed to each other by sandwiching the flat bed frame 41. The notches 44 are formed in conformity to the location of an inlet of a molding resin as indicated by an arrow in FIG. 12.

By providing such notches 44, the first and second suspension pin frames 42 and 43 do not prevent injection of the resin, so that the resin can be uniformly injected to the spaces above and below the flat bed frame 41.

The reason why notches 44 are provided at the both sides of the flat bed frame 41, rather than providing one notch only at either side thereof, is that a plurality of lead frames may be arranged along the direction of injection of the resin, and the frames are successively sealed. Such frames are referred to as multi-row frame.

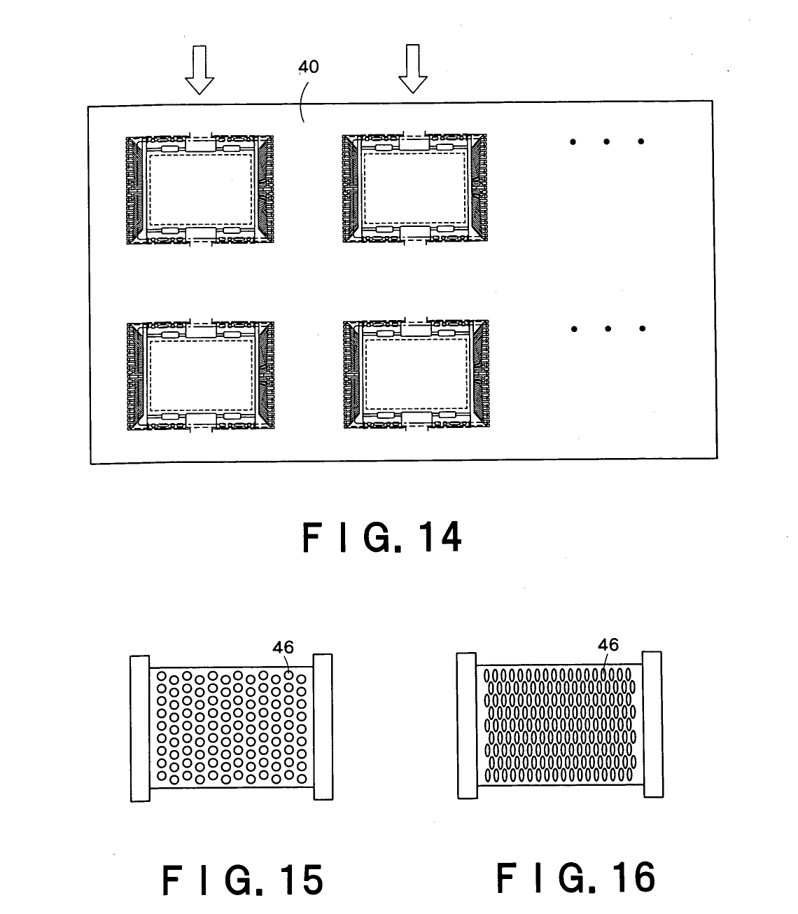

FIG. 14 is a schematic diagram for illustrating a multi-row frame 40. Each of the frames shown in FIG. 14 is configured in the same way as shown in FIG. 12. A chip 1 is mounted on each frame, wire bonding is performed, and then a resin is injected in the direction indicated by the arrow in FIG. 14, and finally, cutting of each chip 1 is performed.

Even when the multi-row frame 40 shown in FIG. 14 is used, the suspension pin frames 42 and 43 according to this embodiment don't disadvantageously change the flow of the resin, because the suspension pin frames 42 and 43 have the notches 44 arranged along the direction of injection of the resin.

As in the first and Second Embodiments, the first and second suspension pin frames 42 and 43 have a plurality of punch holes 45. Through the punch holes 45, the resin can move from the space above the first and second suspension pin frames 42 and 43 to the space below the same and vice versa.

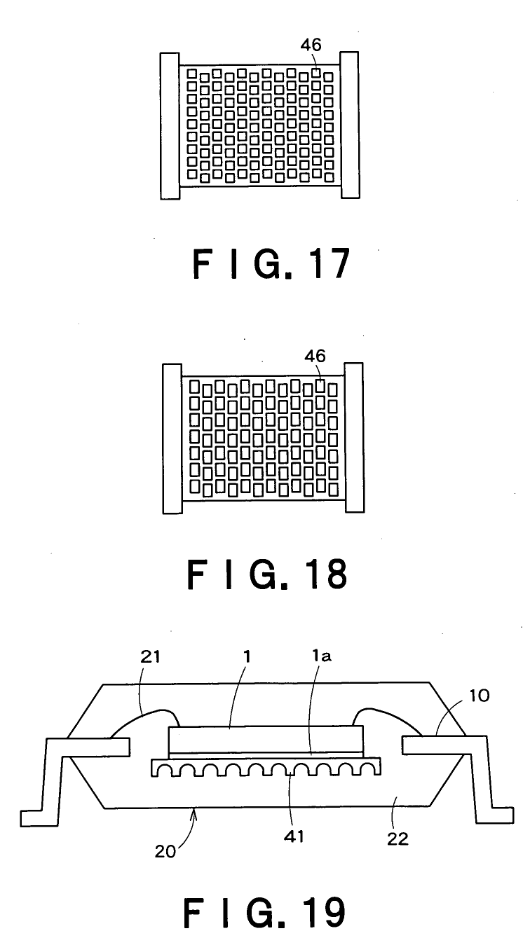

FIGS. 15 and 16 are schematic plan views showing configurations of the bottom surface of the flat bed frame 41. As shown in these drawings, the flat bed frame 41 has many concaves 46 in the back side thereof. Each concave 46 can have any shape. FIG. 15 shows an example in which the concaves 46 have a circular shape, and FIG. 16 shows an example in which the concaves 46 have an elliptical shape. FIGS. 17 and 18 show examples in which the concaves 46 have rectangular shapes.

The concaves 46 are formed in order to improve adhesion between the flat bed frame 41 and the resin. Since individual concaves 46 are filled with the resin, the area of the flat bed frame 41 in contact with the resin increases, and adhesion between the flat bed frame and the resin is improved. Therefore, even if reflowing or the like is carried out after packaging, the flat bed frame and the resin can be prevented from peeling off each other in the package.

In the case of forming the concaves 46 in an elongated shape as shown in FIG. 16, the longitudinal directions of the concaves 46 are preferably aligned with the direction of injection of the resin. This facilitates the flow of the resin along the concaves 46, and an equal resin molding speed can be achieved above and below the flat bed frame 41.

In the case of forming the concaves 46 in an elongated shape, the concaves are not necessarily formed in an elliptical shape. For example, the concaves 46 may be formed in a rectangular shape as shown in FIG. 18.

FIG. 19 is a cross-sectional view taken along the line B-B in FIG. 12, showing a cross-sectional structure of the package after injection of the resin is completed. As shown in this drawing, as in the First Embodiment, injection of a resin 22 is performed after the chip 1 and inner leads 10 are interconnected by bonding wires 21. The molded resin is formed to equal thicknesses above and below the flat bed frame.

As described above, according to the Third Embodiment, the flat bed frame 41 capable of supporting the whole surface of the chip 1 of large size and the suspension pin frames 42 and 43 formed integrally with the flat bed frame 41 are provided, and the suspension pin frames 42 and 43 each has the notch 44 formed at a location corresponding to the inlet of the resin. Therefore, the suspension pin frames 42 and 43 can be prevented from interfering with injection of the resin. In addition, because the flat bed frame 41 has the concaves 46 in the back side thereof, adhesion between the flat bed frame 41 and the resin is improved, the molding speed of the resin becomes equal above and below the flat bed frame 41, and defects such as peel-off can be avoided. In addition, because the flat bed frame 41 has a higher torsional strength than the separated bed frames, the memory IC can be prevented from being damaged by a twisting force.

What is claimed is:

1. A lead frame for semiconductor device, comprising:
at least one bed frame capable of supporting a dual-pin-type chip;
a plurality of suspension pin frames which extend from the bed frame in a first direction, and are disposed apart from each other in a second direction; and
at least two beam frames which extend from the plurality of suspension pin frames in the second direction, and connect the plurality of suspension pin frames at both sides of the chip by sandwiching the chip.

2. A lead frame for semiconductor device according to claim 1, further comprising inner leads which are disposed outside of the chip and connected with pads of the chip by boding wires.

3. A lead frame for semiconductor device according to claim 1, further comprising punch holes formed on the suspension pin frames.

4. A lead frame for semiconductor device according to claim 1,
wherein the plurality of suspension pin frames are connected to two opposite edges of each bed frame.

5. A lead frame for semiconductor device according to claim 4,
wherein the beam frames are provided corresponding to the two opposite edges.

6. A lead frame for semiconductor device according to claim 4,
wherein the bed frame and the plurality of suspension pin frames are formed of the same metal plate.

7. A lead frame for semiconductor device according to claim 1, further comprising a plurality of concaves formed in a back surface side of the bed frame.

8. A lead frame for semiconductor device, comprising:
first and second bed frames which are disposed apart from each other in a first direction and mount a dual-pin-type chip;
first and second suspension pin frames which are disposed in a second direction by sandwiching the first bed frame to support the first bed frame;
third and fourth suspension pin frames which are disposed in a second direction by sandwiching the second bed frame to support the second bed frame;
a first beam frame which connects the first and third suspension pin frames; and
a second beam frame which connects the second and fourth suspension pin frames.

9. A lead frame for semiconductor device according to claim 8,
wherein the first and second bed frames, the first and second suspension pin frames, the third and fourth suspension pin frames, and the first and second beam frames are formed of the same metal plate;
the first bed frame is formed at a location lower than the first and second suspension pin frames; and
the second bed frame is formed at a location lower than the third and fourth suspension pin frames.

10. A lead frame for semiconductor device according to claim 9,
whether a positional relationship between the first and second bed frames and the first to fourth suspension pin frames is set so that a distance between an upper surface of a resin layer disposed on the chip mounted on the first and second bed frames and an upper surface of the chip becomes equal to a distance between a bottom surface of a resin layer disposed under the first and second bed frames and a bottom surface of the chip.

11. A lead frame for semiconductor device according to claim 8, further comprising inner leads connected with pads of the chip by boding wires.

12. A lead frame for semiconductor device according to claim 8, further comprising punch holes formed on at least one of the first to fourth suspension pin frames.

13. A lead frame for semiconductor device, comprising:
a flat bed frame capable of supporting a whole bottom surface of a chip, which has a plurality of concaves at a bottom surface side thereof; and
first and second suspension pin frames which are formed integrated with the flat bed frame, and extend outside along two opposite edges of the flat bed frame, portions of the first and second suspension pin frames being cut to form cut portions.

14. A lead frame for semiconductor device according to claim 13,
wherein the cut portions are formed in vicinity of an inlet of the resin for mold.

15. A lead frame for semiconductor device according to claim 13,
wherein the cut portions are disposed oppositely at both sides of the flat bed frame by sandwiching the flat bed frame.

16. A lead frame for semiconductor device according to claim 13,
wherein the concaves have elongated shapes, and a longitudinal direction of the concaves is in conformity to a direction of the cut portions disposed oppositely.

17. A lead frame for semiconductor device according to claim 13,
wherein steps are formed between the first suspension pin frame and the flat bed frame, and between the second suspension pin frame and the flat bed frame, the first and second suspension pin frames being formed a location higher than the flat bed frame.

18. A lead frame for semiconductor device according to claim 13,
wherein punch holes are formed on the first and second suspension pin frames.
